(19) United States
(12) Patent Application Publication
(10) Pub. No.: US 2008/0124917 A1
(43) Pub. Date: May 29, 2008

(54) Method of manufacturing a semiconductor device having air gaps

(75) Inventors: Jun-Hwan Oh, Incheon (KR); Ju-Hyuck Chung, Suwon-si (KR); Il-Goo Kim, Yongin-si (KR); Hyoung-Sik Kim, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/986,236

(22) Filed: Nov. 20, 2007

(30) Foreign Application Priority Data
Nov. 23, 2006 (KR) 10-2006-0116379

(51) Int. Cl. H01L 21/4763

(52) U.S. Cl. 438/637; 257/E21.597

(57) ABSTRACT

In a method of manufacturing a semiconductor device having air gaps, an organic sacrificial layer pattern is formed on a semiconductor substrate, wherein the organic sacrificial layer pattern includes openings. Metal structures are formed in the openings. The organic sacrificial layer pattern is removed by a plasma ashing treatment using a source gas including oxygen (O₂) and carbon monoxide (CO). An insulating interlayer is formed to have air gaps between the metal structures. Resistance-capacitance (RC) delay and crosstalk between the metal structures may be efficiently suppressed.

### CROSS-REFERENCE TO RELATED APPLICATIONS

This application claims priority under 35 U.S.C. §119 to Korean Patent Application No. 2006-116379, filed on Nov. 23, 2006 in the Korean Intellectual Property Office (KIPO), the contents of which are incorporated herein by reference in their entirety.

### FIELD OF THE INVENTION

Some exemplary embodiments of the present invention relate to methods of manufacturing a semiconductor device. More particularly, some exemplary embodiments of the present invention relate to methods of manufacturing a semiconductor device having air gaps.

### BACKGROUND OF THE INVENTION

Since design specifications of semiconductor devices have decreased to about 90 nm, and even about 32 nm, problems have arisen, such as resistance-capacitance (RC) delay and crosstalk between lines, and increased power consumption. Particularly, as intervals between metal lines decrease, capacitance values such as parasitic capacitance between the metal lines rapidly increase. Thus, the problem of RC delay is becoming a serious issue as the design specifications of semiconductor devices continue to decrease.

Research is being conducted to decrease the resistance of metal lines, as well as parasitic capacitance between the metal lines. For example, research has been conducted on decreasing the resistance of metal lines using a dual-damascene process using a copper (Cu) line. Also, decreasing parasitic capacitance between the metal lines using an insulating interlayer having a low dielectric constant has been proposed. In accordance with the research, a semiconductor device, which has a porous insulation layer having a low dielectric constant of about 2 to 2.9 from an insulation layer including silicon oxide (SiO₂) having a dielectric constant of about 3.8, has been developed. However, the problem of RC delay may become more serious when the design specification of a semiconductor device is decreased to less than about 32 nm.

To solve this problem, technology for forming air gaps between the metal lines has been developed. According to such air-gap technology, it is expected that the parasitic capacitance between the metal lines may be decreased remarkably because air has a dielectric constant of about 1.

Methods of forming air gaps in a semiconductor device are being researched. For example, Uno et al. disclose a method of forming air gaps in a semiconductor device in a paper entitled “Dual Damascene Process for Air-gap Cu Interconnects Using Conventional CVD Films as Sacrificial Layers” as published in Proceedings of the IEEE 2005 International Interconnect Technology Conference, pp 174-176, hereby incorporated by reference in its entirety. According to Uno et al., a selective capping layer is formed on metal lines after forming the metal lines on an insulating interlayer using a dual-damascene process. Then, the insulating interlayer is removed in part or in whole by a dry etching process or a wet etching process. Air gaps are formed between the metal lines by re-forming the insulating interlayer using a conventional chemical vapor deposition (CVD) process.

When the dry etching process is used as mentioned above, there is a problem in that the capping layer on the metal lines may deform or collapse because the metal lines may be vulnerable to an etching gas in the dry etching process. When the wet etching process is used, there is also a problem in that an etchant may permeate into a portion where a barrier metal is relatively thin. Particularly, the surface tension of a liquid due to a capillary phenomenon may collapse thin metal lines.

U.S. Pat. No. 6,423,629 discloses a method of forming metal lines having air gaps using a photoresist pattern. According to U.S. Pat. No. 6,423,629, a copper (Cu) layer or a palladium (Pd) layer as a metal seed layer is formed on a lower layer. Then, a photoresist pattern having a contact hole is formed on the copper (Cu) layer or the palladium (Pd) layer. The contact hole is filled with a metal line by an electroless plating process. The photoresist pattern is then removed by an ashing process. An insulating interlayer is formed to fill up the metal lines to form air gaps between the metal lines. However, when the metal line is formed in the contact hole using a photoresist pattern that is vulnerable to a thermal stress and has a relatively low hardness, it can be difficult to form metal lines having a predetermined structure.

Thus, a new method of manufacturing a semiconductor device is still needed to provide air gaps that may be formed efficiently without metal lines deforming or collapsing.

### SUMMARY OF THE INVENTION

Exemplary embodiments of the present invention provide a method of manufacturing a semiconductor device having air gaps and that is capable of providing improved electrical characteristics.

Exemplary embodiments of the present invention also provide a method of manufacturing a semiconductor device that is capable of readily forming air gaps while preventing metal lines from deforming or collapsing.

However, the present invention should not be construed as limited to the embodiments indicated above. One of ordinary skill in the art would clearly understand that the present invention may have other embodiments or other advantages not indicated above.

According to one aspect of the present invention, there is provided a method of manufacturing a semiconductor device. In the method of manufacturing a semiconductor device, an organic sacrificial layer pattern is formed on a semiconductor substrate, wherein the organic sacrificial layer pattern includes openings. Then, metal structures (e.g., lines) are formed in the openings. The organic sacrificial layer pattern is removed by a plasma ashing treatment using a source gas including oxygen (O₂) and carbon monoxide (CO). An insulating interlayer is formed to have air gaps between the metal structures.

In one exemplary embodiment of the present invention, the organic sacrificial layer pattern may be formed using a material that is substantially harder than a photoresist. For example, the organic sacrificial layer may include near-frictionless carbon (NFC), a bottom anti-reflective coating (BARC), an anti-reflective coating (ARC), an anti-reflective layer (ARL), etc.

In one exemplary embodiment of the present invention, the source gas used in the plasma ashing treatment may further include hydrogen (H₂) or nitrogen (N₂).

In one exemplary embodiment of the present invention, a supporting layer may be formed on the semiconductor substrate before the organic sacrificial layer pattern is formed.

According to another aspect of the present invention, there is provided a method of manufacturing a semiconductor device. In the method of manufacturing a semiconductor device, a semiconductor substrate on which lower lines are formed is provided. An organic sacrificial layer is formed on the semiconductor substrate. A hard mask layer is formed on the organic sacrificial layer. Openings are formed on the organic sacrificial layer using the hard mask layer to form an organic sacrificial layer pattern, wherein the openings partially expose the lower lines. A conductive layer is formed on the organic sacrificial layer pattern to fill the openings. Metal structures (e.g., lines) are formed in the openings by partially removing the conductive layer. The organic sacrificial layer pattern is removed by a plasma ashing treatment using a source gas including oxygen (O₂) and carbon monoxide (CO). An insulating interlayer is formed to have air gaps between the metal structures.

In one exemplary embodiment of the present invention, the conductive layer may include copper (Cu) formed by an electroplating process.

The method of manufacturing a semiconductor device in accordance with exemplary embodiments of the present invention may be applied to a minute electronic device such as a large-scale integrated circuit semiconductor device, a processor, a microelectromechanical (MEM) device, an optoelectronic device, a display device, etc. Particularly, the method of manufacturing semiconductor device in accordance with exemplary embodiments of the present invention may be usefully applied to a central processor unit (CPU), a digital signal processor (DSP), a combination of a CPU and a DSP, an application-specific integrated circuit (ASIC), a logic device, static random access memory (SRAM), etc.

### BRIEF DESCRIPTION OF THE DRAWINGS

The above and other features and advantages of the present invention will become more apparent by describing the detailed exemplary embodiments thereof with reference to the accompanying drawings, in which:

FIGS. 1 to 7 are cross-sectional views illustrating a method of manufacturing a semiconductor device in accordance with example embodiments of the present invention; and

FIGS. 8 to 12 are cross-sectional views illustrating a method of manufacturing a semiconductor device in accordance with other example embodiments of the present invention.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be on, connected to or coupled to the other element or layer, with intervening elements or layers present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (e.g., rotated 90 degrees or at other orientations) and the spatially relative descriptors used herein interpreted accordingly.

The terminology used herein is for the purpose of describing particular embodiments only and is not intended to limit of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

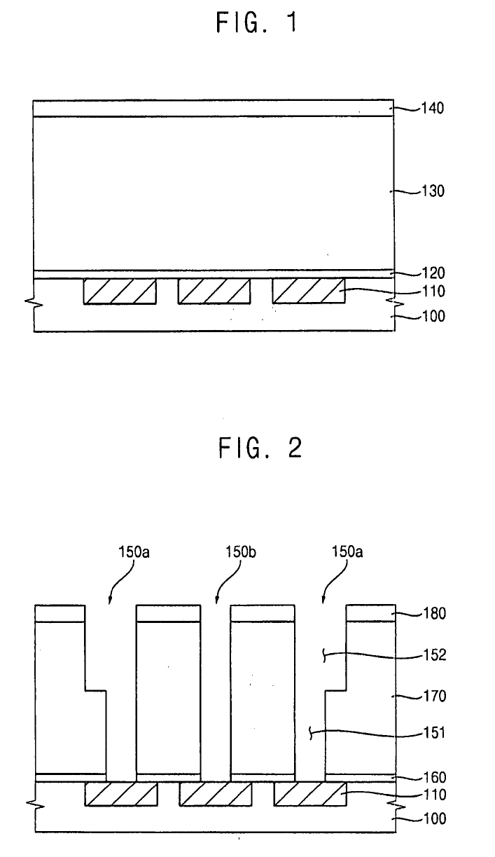

FIGS. 1 to 7 are cross-sectional views illustrating a method of manufacturing a semiconductor device in accordance with exemplary embodiments of the present invention.

Referring to FIG. 1, an etch-stop layer 120, an organic sacrificial layer 130, and a hard mask layer 140 are formed on a substrate 100 sequentially.

The substrate 100 may include a silicon substrate, a silicon-on-insulator (SOI) substrate, a gallium-arsenide (GaAs) substrate, a silicon-germanium (SiGe) substrate, a ceramic substrate, a quartz substrate, a glass substrate for displaying, etc. Various active devices and passive devices may be provided on the substrate 100.

In exemplary embodiments of the present invention, lower lines 110 may be formed on the substrate 100. The lower lines 110 may be formed using various wiring materials, for example, a metal or a metal alloy such as copper (Cu), a copper (Cu) alloy, aluminum (Al), an aluminum (Al) alloy, etc. Copper (Cu) may be selected for forming the lower lines 110 in view of its low electric resistance. Surfaces of the lower lines 110 may be planarized by a planarization process such as a chemical mechanical polishing (CMP) process and/or an etch-back process.

The etch-stop layer 120 prevents the material for forming the lower lines 110 such as copper (Cu) from diffusing. Further, the etch-stop layer 120 prevents the lower lines 110 from being exposed during a dry etching process for forming a via hole and a process for removing a residual filling material after forming a trench to maintain the electrical characteristics of the lower lines 110. The etch-stop layer 120 may be formed using a material having a high etching selectivity with respect to the organic sacrificial layer 130 that may be formed on the etch-stop layer 120. For example, the etch-stop layer 120 may be formed using a material having a dielectric constant of about 3 to 8 such as silicon carbide (SiC), silicon nitride (SiN), silicon carbonitride (SiCN), silicon oxycarbide (SiOC), silicon oxycarbonitride (SiOCN), etc. The etch-stop layer 120 may have a single-layer structure including any one of the above-mentioned materials, or a multilayer structure including a mixture thereof. The etch-stop layer 120 may be formed as thin as possible, in view of the effect of the etch stop layer 120 on the dielectric constant of the entire insulation interlayer. However, the etch-stop layer 120 may be formed to have a sufficient thickness to work as an etch-stop layer 120.

The organic sacrificial layer 130 may be formed using an organic material including carbon (C), hydrogen (H), and oxygen (O). In exemplary embodiments of the present invention, the organic sacrificial layer 130 may be substantially harder than a photoresist. For example, the organic sacrificial layer 130 may include near-frictionless carbon (NFC), a bottom anti-reflective coating (BARC), an anti-reflective coating (ARC), or an anti-reflective layer (ARL) in accordance with a combination ratio of carbon (C), hydrogen (H), and oxygen (O). The sacrificial layer 130 may be formed to have a thickness of about 3,000 to about 20,000 Å from an upper face of the etch-stop layer 120. For example, the organic sacrificial layer 130 may be formed to have a thickness of about 6,000 to about 7,000 Å. The thickness of the organic sacrificial layer 130 may vary in accordance with required characteristics for a semiconductor device.

In some embodiments, when an etching process for an underlying layer is performed using a photoresist pattern as a mask, wherein the photoresist pattern is fit for an exposure source emitting light having a wavelength of about 248 nm, the etch resistance of the photoresist pattern is so small that the photoresist pattern may not be appropriate as a mask for the etching process for the underlying layer. Thus, in exemplary embodiments of the present invention, a hard mask layer 140 may be used as a mask for etching the organic sacrificial layer 130. The photoresist pattern, which has a small etch resistance for a dry etching process, may be used in a patterning process for the hard mask layer 140, and the organic sacrificial layer 130 may be etched using the hard mask pattern that is formed by a patterning process using the photoresist pattern as a mask, as shown in FIG. 2. The hard mask layer 140 may be formed using a silicon compound, metal, or metal oxide. For example, the hard mask layer 140 may be formed using silicon oxide (SiO), silicon nitride (SiN), silicon oxynitride (SiON), silicon carbide (SiC), silicon carbonitride (SiCN), silicon oxycarbide (SiOC), silicon oxycarbonitride (SiOCN), benzocyclobutene (BCB), tantalum (Ta), tantalum nitride (TaN), titanium (Ti), titanium nitride (TiN), aluminum oxide (AlO), boron nitride (BN), or hydrogen silsesquioxane (HSQ). In exemplary embodiments of the present invention, the hard mask layer 140 may have a single-layer structure including any one of the above-mentioned materials such as the silicon compound, the metal, or the metal oxide, or a multilayer structure including a mixture thereof.

Referring to FIG. 2, after the photoresist pattern (not illustrated) is formed on the hard mask layer 140, a hard mask pattern 180 may be formed by etching the hard mask layer 140 using the photoresist pattern as an etch mask.

Openings 150a and 150b partially exposing each of the lower lines 110 may be formed by partially etching the organic sacrificial layer 130 and the etch-stop layer 120 using the hard mask pattern 180. Here, the organic sacrificial layer 130 and the etch-stop layer 120 are converted into an organic sacrificial layer pattern 170 and an etch-stop layer pattern 160 by the formation of the openings 150a and 150b.

After forming the organic sacrificial layer pattern 170 and the etch-stop layer pattern 160, the hard mask pattern 180 may be removed from the organic sacrificial layer pattern 170.

Some openings 150a of the openings 150a and 150b formed through the organic sacrificial layer pattern 170 may have a via hole 151 and a trench 152, and the other openings 150b of the openings 150a and 150b may only have a via hole 151. The openings 150a having the via hole 151 and the trench 152 may be formed by separate photolithography processes for forming the via hole 151 and the trench 152. In contrast, the openings 150b having only the via hole 151 may be formed by one photolithography process for forming the via hole 151. That is, the photolithography process may be performed twice on the organic sacrificial layer pattern 170 to form the openings 150a having the via hole 151 and the trench 152. On the contrary, the photolithography process may be performed once on the organic sacrificial layer pattern 170 to form the openings 150b only having the via hole 151.

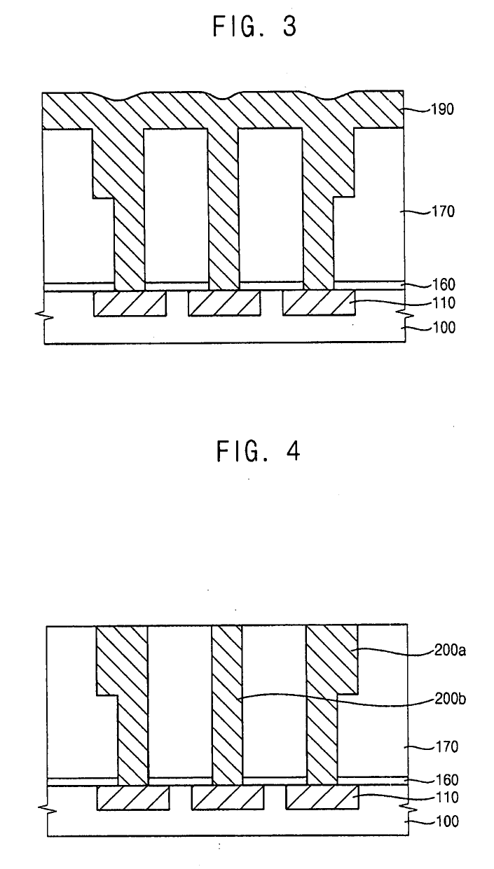

Referring to FIG. 3, a conductive layer 190 may be formed on the lower lines 110 and the organic sacrificial layer pattern 170 partially exposed to sufficiently fill up the openings 150a and 150b. The conductive layer 190 may be formed using a metal or a metal alloy such as aluminum (Al), an aluminum (Al) alloy, copper (Cu), gold (Au), silver (Ag), tungsten (W), or molybdenum (Mo). The above-mentioned materials may be used alone or in a combination thereof. The conductive layer 190 may be formed by a sputtering process and a reflowing process, by a chemical vapor deposition (CVD) process, or by an electroplating process. In exemplary embodiments of the present invention, when the conductive layer 190 is formed by the electroplating process, a seed layer may be formed on the lower layer and/or the substrate 100 to apply a current to an electrolyte.

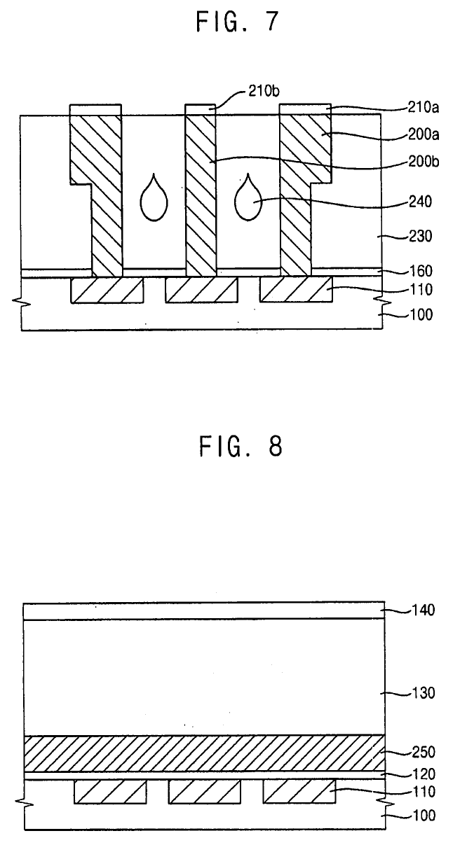

In other exemplary embodiments of the present invention, a barrier metal layer (not shown) may be formed on the lower lines 110 and side faces of the openings 150a and 150b before the conductive layer 190 is formed. For example, when the conductive layer 190 is formed using metal such as copper (Cu), the barrier metal layer may prevent copper (Cu) from the conductive layer 190 from diffusing, so that the barrier metal layer may prevent the dielectric characteristics of an insulating interlayer 230 (referring to FIG. 7) from being deteriorated. The barrier metal layer may be formed using a metal, a metal carbide, or a metal nitride. For example, the barrier metal layer may be formed using tantalum (Ta), tantalum nitride (TaN), titanium nitride (TiN), tungsten nitride (WN), tantalum carbide (TaC), tungsten carbide (WC), titanium silicon nitride (TiSiN), or tantalum silicon nitride (TaSiN). The above-mentioned materials may be used alone or in a combination thereof. The barrier metal layer may be formed by a physical vapor deposition (PVD) process, a CVD process, an atomic layer deposition (ALD) process, a pulsed laser deposition (PLD) process, or an electron beam evaporation process.

Referring to FIG. 4, the conductive layer 190 is partially removed until the organic sacrificial layer pattern 170 is exposed to form metal lines 200a and 200b in the openings 150a and 150b. The metal lines 200a and 200b may be formed by a CMP process, or an etch-back process.

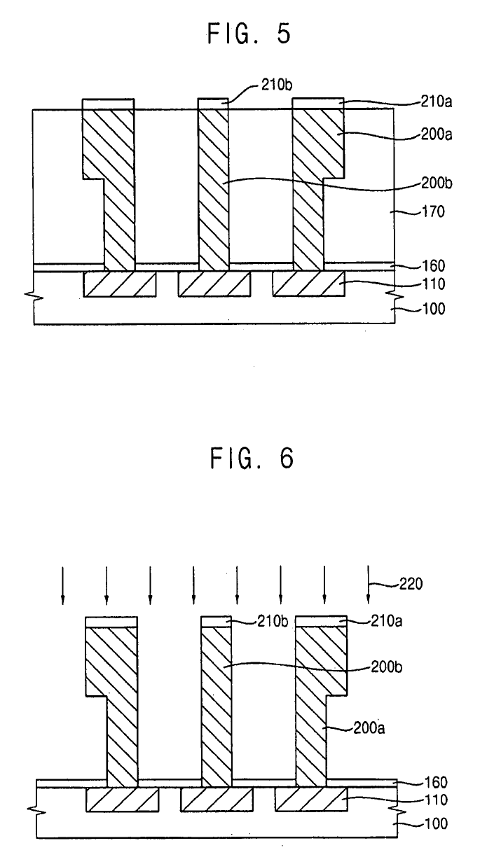

Referring to FIG. 5, capping layer patterns 210a and 210b may be selectively formed on the metal lines 200a and 200b, thereby filling up the openings 150a and 150b. The capping layer patterns 210a and 210b may prevent the metal lines 200a and 200b from being damaged during a plasma ashing process. The capping layer patterns 210a and 210b may be formed by a CVD process, an electroless plating process, or an ALD process. According to exemplary embodiments of the present invention, the capping layer patterns 210a and 210b may remain on the metal lines 200a and 200b that have been finally completed. When the capping layer patterns 210a and 210b remain on the metal lines 200a and 200b, the capping layer patterns 210a and 210b may be formed using a material that may maintain an increasing rate of resistance of the metal lines 200a and 200b within a resistance margin range of a semiconductor device, for example, so that the increasing rate of resistance is maintained to be less than about 50%. The capping layer pattern may be formed using a metal, a metal oxide, a metal phosphide, a metal boride, a metal nitride, or a mixture thereof. For example, the capping layer patterns 210a and 210b may be formed using tungsten (W), tantalum (Ta), titanium (Ti), cobalt tungsten phosphide (CoWP), cobalt tin phosphide (CoSnP), cobalt phosphide (CoP), cobalt boride (CoB), cobalt tin boride (CoSnB), palladium (Pd), indium (In), nickel boride (NiB), tungsten nitride (WN), tantalum nitride (TaN), titanium nitride (TiN), tantalum oxide (TaO), or titanium oxide (TiO).

According to exemplary embodiments of the present invention, when the capping layer patterns 210a and 210b are formed using tantalum oxide (TaO), titanium oxide (TiO), titanium (Ti), tantalum (Ta), tungsten (W), or tungsten nitride (WN), the capping layer patterns 210a and 210b may be formed on the metal lines 200a and 200b by the CVD process.

In other exemplary embodiments of the present invention, when the capping layer patterns 210a and 210b are formed using cobalt tungsten phosphide (CoWP), cobalt tin phosphide (CoSnP), cobalt phosphide (CoP), cobalt boride (CoB), cobalt tin boride (CoSnB), palladium (Pd), indium (In), nickel boride (NiB), etc., the capping layer patterns 210a and 210b may be formed on the metal lines 200a and 200b by the electroless plating process.

In still other exemplary embodiments of the present invention, when the capping layer patterns 210a and 210b are formed using tantalum nitride (TaN), titanium nitride (TiN), etc., the capping layer patterns 210a and 210b may be formed on the metal lines 200a and 200b by the ALD process.

Methods of forming the capping layer patterns 210a and 210b by the electroless plating process are disclosed, for example, in U.S. Patent Application Publication No. US2002/0123220 and a reference entitled “An Electrochemical Study of Electroless Co—W—P Alloy Deposition” as published in Proceedings, 1997 IEEE/Cornell Conference on Advanced Concepts in High Speed Semiconductor Devices and Circuits, Vol. III, pp 192-200, both hereby incorporated by reference in their entirety. Each of the capping layer patterns 210a and 210b may be formed to have a thickness of about 50 to about 500 Å.

Referring to FIG. 6, the organic sacrificial layer pattern 170 may be removed from the metal lines 200a and 200b and the substrate 100 by a plasma ashing treatment 220. According to exemplary embodiments of the present invention, the plasma ashing treatment 220 is performed using a source gas including oxygen (O₂) and carbon monoxide (CO). In other exemplary embodiments of the present invention, hydrogen (H₂) and/or nitrogen (N₂) may be selectively added to the source gas used in the plasma ashing treatment 220.

In exemplary embodiments of the present invention, the plasma ashing treatment 220 is different from a conventional plasma ashing treatment for removing photoresist. For example, only oxygen-containing plasma is used in the conventional plasma ashing treatment. The plasma ashing treatment 220 is also different from a conventional dry etching process because the organic sacrificial layer pattern 170 is substantially isotropically removed by the plasma ashing treatment 220 in accordance with exemplary embodiments of the present invention, and the plasma ashing treatment 220 is performed under a relatively low energy level to prevent damaging the metal lines 200a and 200b. In addition, the plasma ashing treatment 220 is different from a conventional wet etching process because, although the plasma ashing treatment 220 in accordance with exemplary embodiments of the present invention is performed isotropically, an etchant is not used.

In addition to oxygen plasma, carbon monoxide plasma is used to remove the organic sacrificial layer pattern 170 because the hardness of the organic sacrificial layer pattern 170 is stronger than that of a photoresist as indicated above with reference to FIG. 1. When the organic sacrificial layer pattern 170 is removed, the metal lines 200a and 200b are exposed as a whole.

Referring to FIG. 7, the insulating interlayer 230 may be formed on the substrate 100 to fill the gaps between the exposed metal lines 200a and 200b. The insulating interlayer 230 may be formed using a dielectric material having a low dielectric constant and good heat-resistant characteristics. Accordingly, resistance-capacitance (RC) delay and crosstalk between the metal lines 200a and 200b, and increased power consumption may be suppressed. The insulating interlayer 230 may be formed using an organic polymer and/or an inorganic material having a low dielectric constant. For example, the organic polymer having a low dielectric constant may include polyallylether resin, cyclic fluorine resin, a siloxane copolymer, polyallylether fluoride resin, polypentafluorostyrene, polytetrafluorostyrene resin, polyimide fluoride resin, polynaphthalene fluoride, polycide resin, etc. The inorganic material having a low dielectric constant may include undoped silicate glass (USG), tetraethylorthosilicate (TEOS), fluorosilicate glass (FSG), organosilicate glass (OSG), silicon oxycarbide (SiOC or SiOCH), hydrogen silsesquioxane (HSQ), methyl silsesquioxane (MSQ), etc.

The insulating interlayer 230 may be formed by a plasma-enhanced CVD (PECVD) process, a high-density plasma CVD (HDP-CVD) process, an atmospheric pressure CVD (APCVD) process, a spin coating process, etc. The insulation interlayer 230 may be formed to have a thickness of about 3,000 to about 20,000 Å from an upper face of the substrate 100. For example, the insulating interlayer 230 may be formed to have a thickness of about 6,000 to about 7,000 Å. The thickness of the insulating interlayer 230 may vary in accordance with characteristics of a semiconductor device.

Referring to FIG. 7 again, when the insulating interlayer 230 is formed on the substrate 100 to fill the gaps between the metal lines 200a and 200b as described above, air gaps 240 may be formed in the insulating interlayer 230 between the metal lines 200a and 200b. When the semiconductor device has a design specification of less than about 45 nm, the gaps between the metal lines 200a and 200b may become narrower, so the air gaps 240 may be more easily formed in the insulating interlayer 230 between the metal lines 200a and 200b.

According to a method of manufacturing a semiconductor device in accordance with exemplary embodiments of the present invention, the organic sacrificial layer pattern 170 is removed by the plasma ashing treatment 220 using the source gas including oxygen (O₂) and carbon monoxide (CO) after forming the metal lines 200a and 200b using the organic sacrificial layer pattern 170. Then, the insulating interlayer 230 is formed to fill the gaps between the metal lines 200a and 200b; thus, the air gaps 240 may be more easily formed in the insulating interlayer 230 between the metal lines 200a and 200b. The air gaps 240 may decrease parasitic capacitance between the metal lines 200a and 200b, so that RC delay and crosstalk between the metal lines 200a and 200b may be suppressed. The methods of forming the insulating interlayer 230 having air gaps as described above may be employed in methods of forming other metal structures different from that of the metal lines 200a and 200b in accordance with the present invention.

FIGS. 8 to 12 are cross-sectional views illustrating a method of manufacturing a semiconductor device in accordance with other exemplary embodiments of the present invention. The method of manufacturing a semiconductor device illustrated in FIGS. 8 to 12 is substantially the same as the method of manufacturing a semiconductor device illustrated in FIGS. 1 to 6, except for a lower supporting layer. Thus, the same reference numerals will be used to refer to the same elements and any further explanation in this regard will be omitted.

Referring to FIG. 8, an etch-stop layer 120, a supporting layer 250, an organic sacrificial layer 130, and a hard mask layer 140 are formed on an upper face of a substrate 100 sequentially.

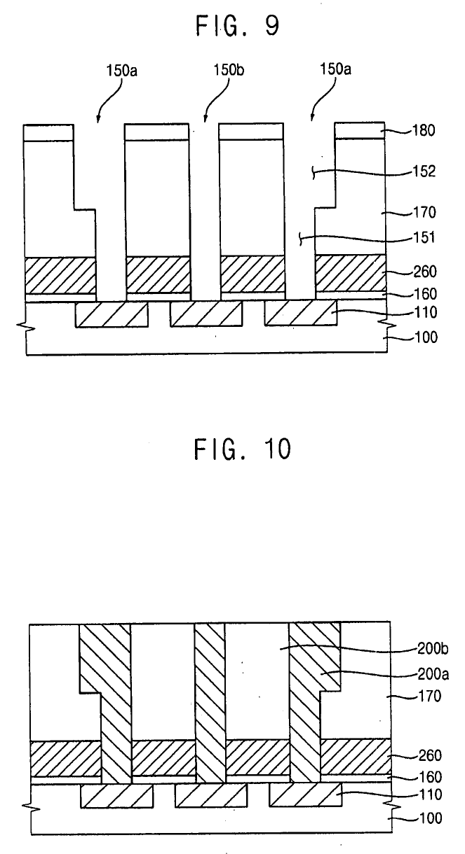

In exemplary embodiments of the present invention, when the organic sacrificial layer pattern 170 is removed by a plasma ashing treatment 220 as discussed later, the supporting layer 250 is not removed. The supporting layer 250 is converted into a supporting layer pattern 260 (referring to FIG. 9) to remain on an etch-stop layer pattern 160. The supporting layer 250 may be formed using a material having a low dielectric constant. For example, the supporting layer 250 may be formed using silicon carbide (SiC), silicon oxycarbide (SiOC or SiOCH), or silicon nitride (SiN).

The supporting layer pattern 260 may improve the structural stability of the metal lines 200a and 200b in a plasma ashing treatment 220 as illustrated in FIG. 10. In exemplary embodiments of the present invention, the supporting layer 250 may be formed to have a thickness of about a quarter to about half of the thickness of the metal lines 200a and 200b. When the supporting layer 250 is formed to have a thickness of about less than a quarter of the thickness of the metal lines 200a and 200b, an increase in the structural stability of the metal lines 200a and 200b due to the supporting layer 250 may not be sufficient. On the other hand, when the supporting layer 250 is formed to have a thickness of about more than half of the thickness of the metal lines 200a and 200b, the decrease in the dielectric constant of the insulating interlayer 230 due to the air gaps 240 may not be sufficient. The thickness of the supporting layer 250 may, however, vary in accordance with characteristics of a semiconductor device.

Referring to FIGS. 8 and 9, a photoresist pattern (not shown) is formed on the hard mask layer 140. Then, the hard mask layer 140 is etched using the photoresist pattern as an etch mask to form the hard mask pattern 180 on the organic sacrificial layer 130.

Using the hard mask pattern 180 as an etching mask, openings 150a and 150b may be formed by partially removing the organic sacrificial layer 130, the supporting layer 250, and the etch-stop layer 120. The openings 150a and 150b may partially expose the semiconductor substrate 100 and/or the lower lines 110. Accordingly, the organic sacrificial layer 130, the supporting layer 250, and the etch-stop layer 120 are converted into the organic sacrificial layer pattern 170, the supporting layer pattern 260, and the etch-stop layer pattern 160, respectively.

As discussed above, the hard mask pattern 180 may be removed form the organic sacrificial layer pattern 170. Then, a conductive layer may be formed on the organic sacrificial layer pattern 170 to sufficiently fill the openings 150a and 150b.

Referring to FIG. 10, the conductive layer is partially removed until the organic sacrificial layer pattern 170 is exposed to form metal lines 200a and 200b in the openings 150a and 150b. The metal lines 200a and 200b may be formed by a CMP process, or an etch-back process.

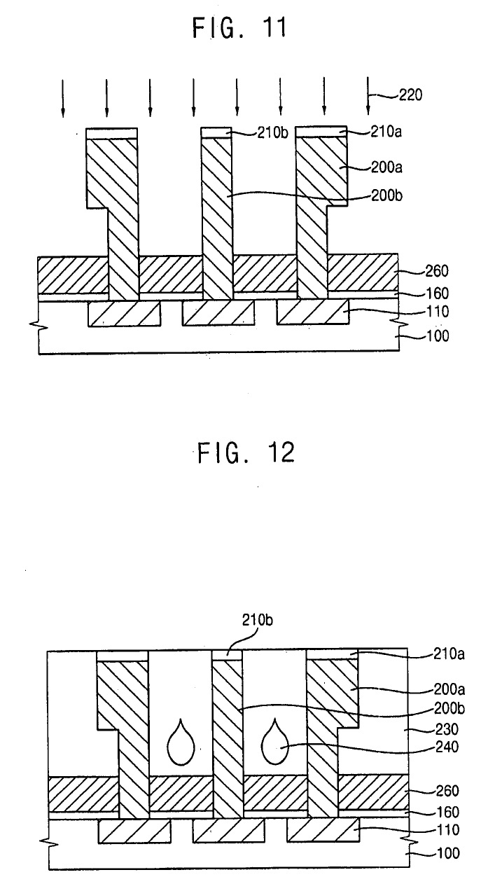

Referring to FIG. 11, capping layer patterns 210a and 210b may be selectively formed on the metal lines 200a and 200b. Then, the organic sacrificial layer pattern 170 is removed by a plasma ashing treatment. In the plasma ashing treatment, the supporting layer 250 is not removed. As discussed above, the plasma ashing treatment 220 may be performed using a source gas including oxygen (O₂) and carbon monoxide (CO). Hydrogen (H₂) and/or nitrogen (N₂) may be selectively added to the source gas used in the plasma ashing treatment 220.

Referring to FIG. 12, the insulating interlayer 230 may be formed on the supporting layer pattern 260 to fill the gaps between the exposed metal lines 200a and 200b. The insulating interlayer 230 may be formed using a material having a low dielectric constant such as an organic polymer or an inorganic material having a low dielectric constant.

When the insulating interlayer 230 is formed as described above, air gaps 240 may be formed in the insulating interlayer 230 between the metal lines 200a and 200b.

According to methods of manufacturing a semiconductor device in accordance with other exemplary embodiments of the present invention, the air gaps 240 may be formed to be nearer to the portion of the metal lines 200a and 200b formed in the trench, so that parasitic capacitance between the metal lines 200a and 200b may be efficiently decreased. Thus, RC delay and crosstalk between the metal lines 200a and 200b may be suppressed more effectively.

According to exemplary embodiments of the present invention, after metal lines are formed using an organic sacrificial layer, the organic sacrificial layer is removed by a plasma ashing treatment using a source gas including oxygen (O₂) and carbon monoxide (CO). Then, an insulating interlayer having air gaps is formed to fill the gaps between the metal lines. Thus, a semiconductor device may be manufactured without the metal lines deforming or collapsing, and the semiconductor device may have improved electrical characteristics due to the air gaps.

The foregoing is illustrative of the present invention and is not to be construed as limiting thereof. Although exemplary embodiments of the present invention have been described, those skilled in the art will readily appreciate that many modifications of the exemplary embodiments are possible without materially departing from the novel teachings and advantages of the present invention. Accordingly, all such modifications are intended to be included within the scope of this invention as defined in the claims. It is to be understood that the foregoing is illustrative of the present invention and is not to be construed as limited to the embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a semiconductor device, comprising:
forming an organic sacrificial layer pattern on a semiconductor substrate, wherein the organic sacrificial layer pattern includes openings;
forming metal structures in the openings;
removing the organic sacrificial layer pattern by a plasma ashing treatment using a source gas including oxygen (O₂) and carbon monoxide (CO); and
forming an insulating interlayer having air gaps between the metal structures.

2. The method of claim 1, further comprising selectively forming capping layers on the metal structures.

3. The method of claim 2, wherein the capping layers comprise at least one selected from the group consisting of tungsten (W), tantalum (Ta), titanium (Ti), cobalt tungsten phosphide (CoWP), cobalt tin phosphide (CoSnP), cobalt phosphide (CoP), cobalt boride (CoB), cobalt tin boride (CoSnB), palladium (Pd), indium (In), nickel boride (NiB), tungsten nitride (WN), tantalum nitride (TaN), titanium nitride (TiN), tantalum oxide (TaO), and titanium oxide (TiO).

4. The method of claim 1, wherein the organic sacrificial layer pattern comprises one selected from the group consisting of near-frictionless carbon (NFC), a bottom anti-reflective coating (BARC), an anti-reflective coating (ARC), and an anti-reflective layer (ARL).

5. The method of claim 1, wherein the metal structures comprise at least one selected from the group consisting of aluminum (Al), an aluminum (Al) alloy, copper (Cu), gold (Au), silver (Ag), tungsten (W), and molybdenum (Mo).

6. The method of claim 1, wherein the source gas further comprises hydrogen (H₂) or nitrogen (N₂).

7. The method of claim 1, wherein the insulating interlayer comprises one selected from the group consisting of polyallylether resin, cyclic fluorine resin, a siloxane copolymer, polyallylether fluoride resin, polypentafluorostyrene, polytetrafluorostyrene resin, polyimide fluoride resin, polynaphthalene fluoride, polycide resin, undoped silicate glass (USG), tetraethylorthosilicate (TEOS), fluorosilicate glass (FSG), organosilicate glass (OSG), hydrogen silsesquioxane (HSQ), and methyl silsesquioxane (MSQ).

8. The method of claim 1, wherein some of the openings have a via hole and a trench.

9. The method of claim 1, further comprising forming a supporting layer pattern on the semiconductor substrate before forming the organic sacrificial layer pattern.

10. The method of claim 9, wherein the supporting layer pattern has a thickness of about a quarter to about half of the thickness of the metal structures.

11. The method of claim 10, wherein the supporting layer pattern comprise one selected from the group consisting of silicon carbide (SiC), silicon oxycarbide (SiOC or SiOCH), and silicon nitride (SiN).

12. The method of claim 1, wherein forming the organic sacrificial layer pattern on the semiconductor substrate comprises:
forming an organic sacrificial layer on the semiconductor substrate;
forming a hard mask pattern on the organic sacrificial layer; and
partially etching the organic sacrificial layer using the hard mask pattern to form the openings.

13. The method of claim 12, wherein the hard mask comprises one selected from the group consisting of silicon oxide (SiO), silicon nitride (SiN), silicon oxynitride (SiON), silicon carbide (SiC), silicon carbonitride (SiCN), silicon oxycarbide (SiOC), silicon oxycarbonitride (SiOCN), benzocyclobutene (BCB), tantalum (Ta), tantalum nitride (TaN), titanium (Ti), titanium nitride (TiN), aluminum oxide (AlO), boron nitride (BN), and hydrogen silsesquioxane (HSQ).

14. A method of manufacturing a semiconductor device, comprising:
providing a semiconductor substrate, wherein lower structures are formed on the semiconductor substrate;
forming an organic sacrificial layer on the semiconductor substrate;
forming a hard mask on the organic sacrificial layer;
forming an organic sacrificial layer pattern by partially etching the organic sacrificial layer using the hard mask, wherein the organic sacrificial layer pattern includes openings partially exposing the lower structures;
forming a conductive layer on the organic sacrificial layer pattern, wherein the conductive layer fills the openings;
forming metal structures in the openings by partially removing the conductive layer;
removing the organic sacrificial layer pattern by a plasma ashing treatment using a source gas including oxygen (O₂) and carbon monoxide (CO); and
forming an insulating interlayer having air gaps between the metal structures.

15. The method of claim 14, wherein the conductive layer is formed by an electroplating process using copper (Cu).

16. The method of claim 14, wherein the source gas further comprises hydrogen (H₂) or nitrogen (N₂).

17. The method of claim 14, wherein the insulating interlayer comprises one selected from the group consisting of polyallylether resin, cyclic fluorine resin, a siloxane copolymer, polyallylether fluoride resin, polypentafluorostyrene, polytetrafluorostyrene resin, polyimide fluoride resin, polynaphthalene fluoride, polycide resin, USG, TEOS, FSG, OSG, HSQ, and MSQ.
